(19) United States
(12) Patent Application Publication
(10) Pub. No.: US 2005/0240846 A1
(43) Pub. Date: Oct. 27, 2005

(54) Accurate Generation of Scan Enable Signal when Testing Integrated Circuits Using Sequential Scanning Techniques

(75) Inventors: Girish A. MADPUWAR, Chandrapur MS (IN); Shankaranarayana Karantha DESHAMANGALA, Mangalore (IN); Hasanuzzaman SHEIKH, Kolkata (IN)

Correspondence Address: TEXAS INSTRUMENTS INCORPORATED, P O BOX 655474, M/S 3999, DALLAS, TX, 75265, US

(73) Assignee: TEXAS INSTRUMENTS INCORPORATED, Dallas, TX (US)

(21) Appl. No.: 10/709,240

(22) Filed: Apr. 23, 2004

(51) Int. Cl. G01R 31/28

(52) U.S. Cl. 714/726

(57) ABSTRACT

An accurate scan enable signal may be generated from an external scan enable (e.g., generated by test equipment). The external scan enable signal may contain transitions from scan mode to capture mode, and vice versa. The accurate scan enable signal may be generated to time transitions from scan mode to capture mode synchronous with a clock signal, and pass the transitions from capture mode to scan mode asynchronously.

### BACKGROUND OF INVENTION

1. Field of the Invention

The present invention relates to testing of integrated circuits, and more specifically to a method and apparatus for accurate generation of a scan enable signal when testing integrated circuits using a sequential scanning technique such as Automatic Test Pattern Generation (ATPG).

2. Related Art

Integrated circuits are often tested to verify whether the circuits operate in a desired manner. For example, an integrated circuit may be tested to ensure that each component (within the integrated circuit) generates desired outputs in response to a corresponding input combination.

Sequential scanning techniques are often employed to test integrated circuits. As is well known in the relevant arts, Automatic Test Pattern Generation (ATPG) is an example of such a sequential scanning approach. In a typical scenario, the memory elements (e.g., flip-flops) are connected in sequence, and a desired sequence of bits (“test pattern”) is sequentially scanned into the memory elements. The circuit is said to be in a ‘scan mode’ (or loading mode) when a test pattern is being scanned into the memory elements of the circuit.

An integrated circuit may be switched from the scan mode to a capture mode, and the results generated by various combinational logic elements (based on the scanned test pattern) may be stored in the corresponding memory elements. The generated outputs may be examined to verify whether the integrated circuit operates in a desired manner.

It is desirable to control the memory elements to switch from the scan mode to capture mode and vice versa. In general such control is performed using a scan enable signal. Each memory element receives a scan enable signal and operates in scan mode for one logic value and in capture mode for another logic value of scan enable signal. For example, memory elements operate in scan mode when scan enable signal is logic 1 and in capture mode otherwise.

Thus, during testing, it is desirable to switch a scan enable signal from one logic value to another logic value. In general, it is desirable to generate a scan enable signal to ensure that the testing is performed accurately.

### BRIEF DESCRIPTION OF DRAWINGS

The present invention will be described with reference to the following accompanying drawings.

Figure (FIG.) 1 is a block diagram illustrating an example environment in which the present invention can be implemented.

FIG. 2 is a block diagram illustrating the details of an example integrated circuit in which the present invention can be implemented.

FIG. 3 is a timing diagram of various signals illustrating the general operation of various memory elements in one embodiment.

FIG. 4 is a block diagram of a flip-flop illustrating the details of one prior embodiment for generating a scan enable signal.

FIG. 5A is a block diagram of a clock gating circuit illustrating the problems encountered in another prior embodiment operating in a high speed environment.

FIG. 5B is a timing diagram illustrating the details of changes in various signals in an embodiment of the clock gating circuit.

FIG. 6 is a flow chart illustrating a method according to an aspect of the present invention.

FIG. 7 is a block diagram illustrating the details of a presettable circuit, which generates an accurate scan enable signal in an embodiment of the present invention.

FIG. 8 is a block diagram illustrating the details of a gating circuit, which generates an accurate scan enable signal in an alternative embodiment of the present invention.

FIG. 9 is a timing diagram illustrating the timing relationship of various signals in generating an accurate scan enable signal according to various aspects of the present invention.

FIG. 10 is a block diagram illustrating the manner in which an integrated circuit can be tested using an accurate scan enable signal generated according to various aspects of the present invention.

In the drawings, like reference numbers generally indicate identical, functionally similar, and/or structurally similar elements. The drawing in which an element first appears is indicated by the leftmost digit(s) in the corresponding reference number.

### DETAILED DESCRIPTION

1. Overview

An aspect of the present invention may generate an accurate scan enable signal, which is deactivated (transitioning from scan mode to capture mode) synchronously (changing with reference to a clock signal) and activated (transitioning from capture mode to scan mode) asynchronously (changing independent of clock signal). As a result, one or more of several problems encountered in the prior art may be overcome as described below in further detail.

Several aspects of the invention are described below with reference to examples for illustration. It should be understood that numerous specific details, relationships, and methods are set forth to provide a full understanding of the invention. One skilled in the relevant art, however, will readily recognize that the invention can be practiced without one or more of the specific details, or with other methods, etc. In other instances, well_known structures or operations are not shown in detail to avoid obscuring the invention.

2. Example Environment

FIG. 1 is a block diagram illustrating an example environment in which the present invention may be implemented. Example environment 100 is shown containing test equipment 110 and integrated circuit 150. As described below in further detail, integrated circuit 150 can be tested accurately using test equipment 110.

Test equipment 110 may send a sequence of scanned bits on sd_in 103 at time points specified by clock signal on path 101. Scan enable (SE) on path 102 may be set to logic high when the scanned bits are provided, and to logic low to transition to the capture mode. Test equipment 110 may receive data bits on sd_out 105 representing the evaluation outputs. The received data bits can be used to verify proper operation of integrated circuit 150.

SE signal is referred to as an external scan enable signal merely to differentiate from an accurate scan enable signal generated according to various aspects of the present invention. In general, the (accurate) scan enable signal needs to be generated while meeting several requirements. Some example requirements are illustrated with reference to the details of operation of an embodiment of integrated circuit 150.

3. Integrated Circuit

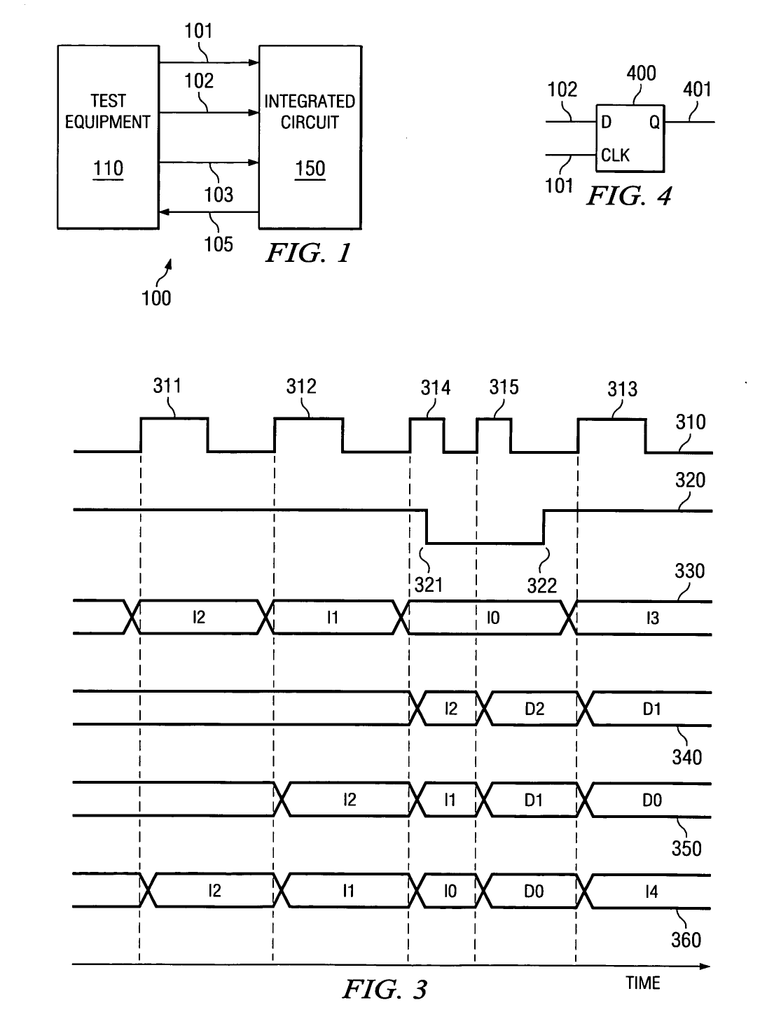

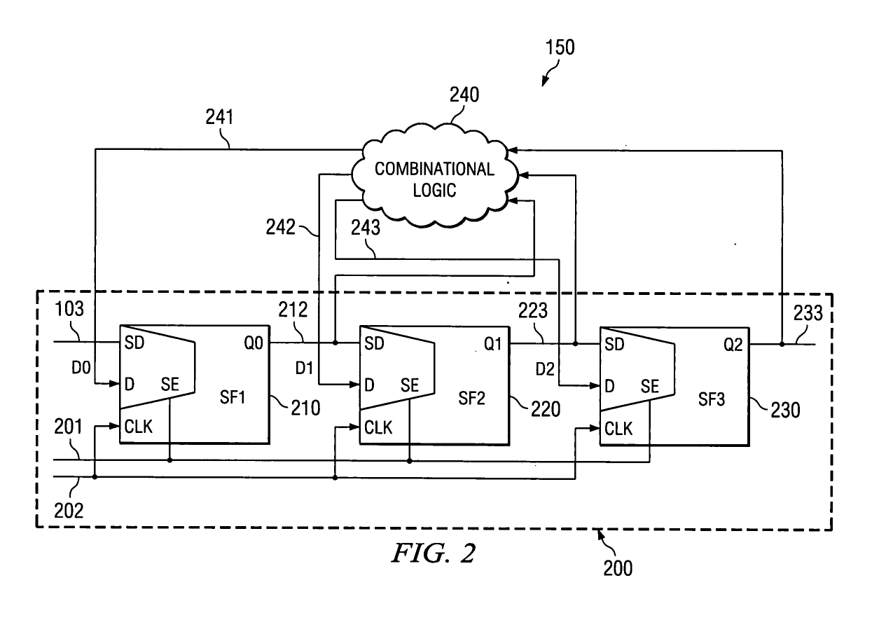

FIG. 2 is a block diagram illustrating the details of integrated circuit 150 in one embodiment. Integrated circuit 150 is shown containing only the relevant components to illustrate various aspects of the present invention. However, integrated circuits generally contain many more components. Integrated circuit 150 is shown containing scan register 200 and combinational logic 240.

Scan register 200 is shown containing scan flip-flops 210, 220 and 230. Each scan flip-flop may be implemented as a combination of a multiplexer and a flip-flop, as logically depicted in FIG. 2. The scan flip-flops are connected in sequence, also as shown. Each scan flip-flop 210, 220 and 230 contains inputs SD, D, clk, SE and output Q.

The clk and SE inputs of all flip-flops are respectively connected to a clock signal on path 202 and a scan enable signal on path 201. The clk on path 202 may correspond to clock signal on path 101. The manner in which (accurate) scan enable signal on path 201 may be generated according to various aspects of the present invention is described in sections below.

The D-input of scan flip-flops 210, 220 and 230 is connected to the output of combinational logic 240 on respective paths 241, 242 and 243. The output of each flipflop is connected to SD-input of the next flip-flop except that the SD-input of flip-flop 210 is connected to sd_in 103. The output of flip-flop 230 on path 233 is provided as sd_out 105.

Combinational logic 240 may perform various logical operations required in integrated circuit 150. Combinational logic 240 is shown receiving outputs from each scan flip-flop and also generating D-inputs to each scan flip-flop. Merely for illustration, combinational logic 240 is shown receiving outputs 212, 223 and 233 of the scan flip-flops, however, the outputs may be provided as inputs to another combinational logic (not shown) in the integrated circuit. The operation of scan register 200, which receives sd_in 103 and provides sd_out 105, is described below.

Broadly, scan flip-flops 210, 220 and 230 are initially initialized with the values on path sd_in 103 in scan mode, and then store the output values received from combinational logic 240 in capture mode. After capturing the output values, the captured values may be shifted out on path 105, while potentially scanning in the next scan sequence for the next evaluation.

It may be appreciated that scan enable signal 201 needs to change from one logic value to another logic value for transitions between capture mode and scan mode. For example, when scan enable signal 201 is high (scan mode), each scan flip-flop 210, 220 and 230 shifts the received bits on sd_in 103, one bit in each cycle of clock signal 202. When scan enable signal 201 is low (capture mode), each scan flip-flop 210, 220 and 230 stores respective output 241, 242 and 243 on corresponding D-inputs. The timing diagram of FIG. 3 further illustrates general operation of various components of FIG. 2.

FIG. 3 is a timing diagram of various signals illustrating the general operation of various memory elements contained in an embodiment of scan register 200. Lines 310, 320, 330, 340, 350 and 360 respectively represent clock 202, scan enable 201, sd_in 103, outputs 233, 223 and 212. The timing diagram is drawn assuming that flip-flops 210, 220 and 230 are respectively initialized to I0, I1 and I2, and the values received by the three flip-flops equal D0, D1 and D2 in capture mode.

Line 310 is shown containing low speed clock pulses 311, 312 and 313, and high speed clock pulses 314 and 315. In general, shifting is performed with a low speed clock and capturing is performed with a high speed clock when testing an integrated circuit designed for operation at high speed.

Line 320 is shown at logic high at rising edge of clock pulses 311, 312 and 314 in scan mode, and changes to logic low at time point 321 after the rising edge of the clock pulse 314. The change after the rising edge of clock pulse 314 enables shifting of the last bit of a scan sequence.

It may be observed that line 320 is at logic low during clock pulse 315, in which the outputs of combinational logic are captured. In addition, line 320 is shown changing from logic low to logic high at time point 322 before the rising edge of clock pulse 313. The return of line 320 to logic high enables shifting out the captured values, in addition to shifting in the next scan sequence for the next evaluation.

Line 330 is shown changing values during each low speed clock pulse, representing the bit scanned in the corresponding clock cycle. Lines 340, 350 and 360 are shown with values I2, I1 and I0 respectively immediately after the rising edge of clock pulse 314, indicating that the desired bit values are scanned into the flip-flops.

Lines 340, 350 and 360 are further shown with captured values D2, D1 and D0 respectively immediately after the rising edge of clock pulse 315, indicating that the output values generated by combinational logic 240 are latched/stored in the respective flip-flops. As may be appreciated, scan enable (line 320) is at logic low at the rising edge of clock pulse 315, causing the evaluated values to be latched into the flip-flops. Line 360 is shown with value 14 during clock pulse 313, indicating that the first value of the next scan sequence is scanned in when scan enable is at logic high (scan mode).

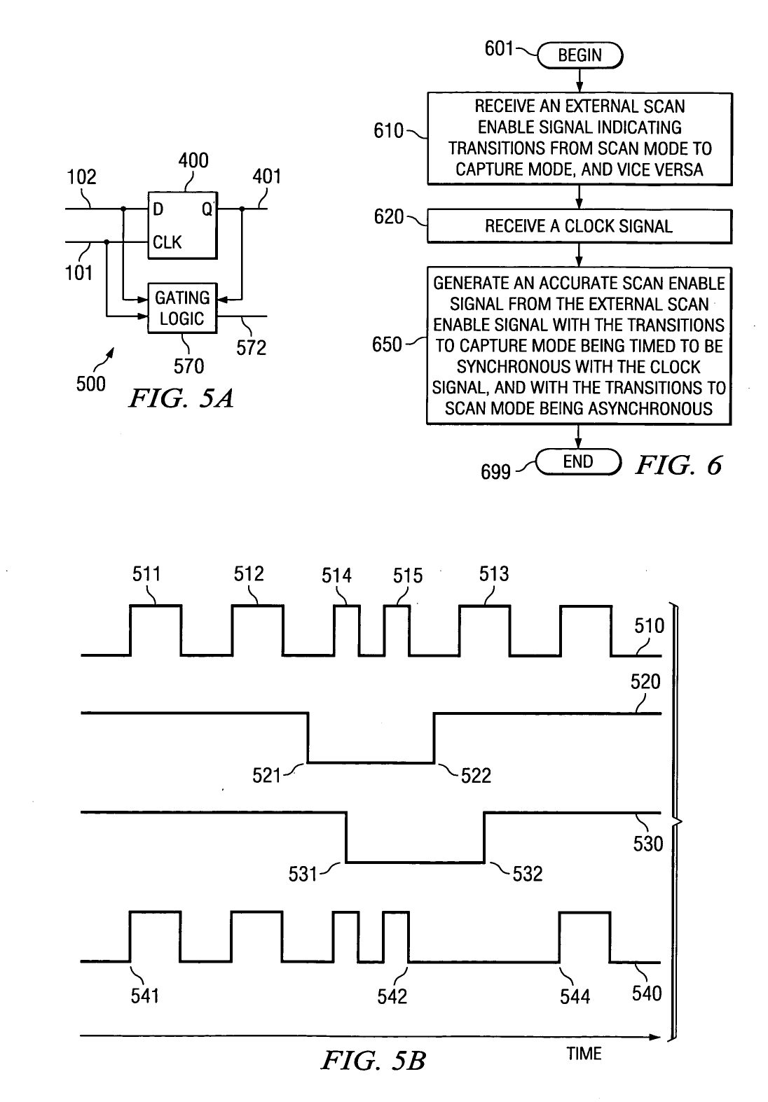

It may be observed that scan enable 201 (line 320) needs to change from one logic value to other logic value, while permitting the use of high and low speed clock pulses. One problem in changing scan enable 201 at high speed is that the test equipment may not generate precisely such high speed signals (scan enable). In addition, the propagation delays in the path of scan enable signal would delay the change to reach all the flip-flops in scan register 200. One approach to address such problems is described below with reference to FIGS. 4 and 5.

4. Prior Approaches

FIG. 4 is a block diagram of a flip-flop illustrating the details of one prior embodiment operating in a high speed environment. Merely for illustration, the description is provided with reference to FIGS. 1, 2 and 3.

Flip-flop 400 receives external scan enable signal SE 102 on D-input, clock 101 on clk input and generates a registered scan enable signal se_reg on path 401. Se_reg 401 is provided as scan enable signal on path 201 to scan register 200 of FIG. 2. Clock 101 may be generated similar to signal 310 described above with reference to FIG. 3.

Test equipment can change external scan enable signal SE 102 in a fairly large window in a low speed clock period before start of the high speed clock pulses, and flip-flop 400 propagates SE 102 on path 401 only at the rising edge of the first high speed clock pulse (i.e., 314 of FIG. 3). As a result, se_reg 401 changes from logic high to low between the two high speed clock pulses as desired. Thus, test equipment need not generate a precise high speed scan enable signal.

One problem with such registered scan enable signal is that undesired values may be captured when changing from captured mode back to scan mode since the registered scan enable signal se_reg 401 may not change before the first low speed clock pulse (in the illustrative example, clock pulse 313) immediately after the capture mode, as described below in further detail.

With reference to FIG. 3, se_reg 401 changes from low level to high level only after the rising edge of clock pulse 313 since flip-flop 400 propagates on path 401 the change in SE 102 only with the rising edge of clock pulse 313. Due to the logic low of se_reg 401 at the rising edge of clock pulse 313, undesired values may be captured into flip-flops 210, 220 and 230. The values captured in the capture mode may be lost, and thus not be available for comparison with expected values. The manner in which such problems are addressed in one prior approach is described below with reference to FIGS. 5A and 5B.

FIG. 5A is a block diagram of clock gating circuit 500 containing flip-flop 400 and gating logic 570. Each component is described below again with reference to FIGS. 1, 2 and 3 for illustration. Gating logic 570 addresses the problem noted above with reference to FIG. 4, as described below.

Gating logic 570 generates clock 572 from clock 101 based on input signals SE 102 and se_reg 401, and provides the generated clock on path 202 to scan register 200. Specifically, gating logic 570 stops providing clock 101 to scan register 200 when SE 102 is at logic high and se_reg 401 is at logic low (during clock pulse 313) even after capture mode.

As a result, scan register 200 does not perform any shift operations until clock 202 is operative (that is, until se_reg 401 changes to logic high). Thus, scan register 200 does not capture the undesired values during clock pulse 313. Various signals in clock gating circuit 500 are described below with reference to FIG. 5B.

FIG. 5B is a timing diagram depicting the details of changes in various signals in clock gating circuit 500. Lines 510, 520, 530 and 540 respectively represent clock 101, external scan enable SE 102, registered scan enable se_reg 401 and gated clock 202.

Line 510 is shown containing low speed clock pulses 511, 512 and 513, and high speed clock pulses 514 and 515.

Line 520 is shown at logic high at rising edge of clock pulses 511 and 512 in scan mode, and changes to logic low at time point 521 after the rising edge of clock pulse 512. The change after the rising edge of clock pulse 512 enables line 530 to change after the rising edge of clock pulse 514. In addition, line 520 is shown changing from logic low to logic high at time point 522 before the rising edge of clock pulse 513.

Line 530 is shown at logic high at rising edge of clock pulses 511, 512 and 514 in scan mode, and changes to logic low at time point 531 after the rising edge of the clock pulse 514. The change after the rising edge of clock pulse 514 enables shifting of the last bit of a scan sequence using a rising edge of the high speed clock signal.

It may be observed that line 530 is at logic low during clock pulse 515, in which the outputs of combinational logic are captured. In addition, line 530 is shown changing from logic low to logic high at time point 532 after the rising edge of clock pulse 513 since se_reg 401 changes with the rising edge of clock signal 101. Even though line 530 (se_reg 401) is at logic low at the rising edge of clock pulse 513, scan register 200 does not capture undesired values due to the stoppage of clock signal as described below with reference to line 540.

Line 540 (clock 202 corresponding to output 572 of gating logic 570) is shown changing similar to line 510 between time points 541 and 542, and from time point 544. Line 540 is shown at logic low between time points 542 and 544, which indicates that clock 101 is not provided (or stopped) as gated clock 202 in that duration. The clock is stopped since line 530 is still at logic low even if line 520 is at logic high after time point 522.

Due to the stoppage of clock signal during clock pulse 513, scan register 200 may not capture the undesired values. However, clock gating circuit 200 has one or more problems as described below.

5. Problems with Clock Gating

One problem with above described prior approach is that gating logic 570 may need to be implemented as a complex logic since gating logic 570 depends on both SE 102 and se_reg 401. In addition, gating logic 570 may introduce a substantial amount of delay in the path of clock signal and thus clock balancing is required, which introduces additional complexities in providing solutions.

Incorrect/inaccurate implementation of clock gating results in glitches in the clock path, which may lead to unpredictable results (for example, shifting undesired values). In addition, approaches based on stoppage of clock signal may require an extra clock cycle to start shifting the data out. The manner in which a precise/accurate scan enable signal can be generated (while overcoming one or more problems noted above) according to various aspects of the present invention is described below.

6. Method

FIG. 6 is a flow chart illustrating a method using which an accurate scan enable signal may be generated according to an aspect of the present invention. The method is described with reference to FIGS. 1 and 2 for illustration. Various aspects of the present invention can be implemented in other environments as well. The method begins in step 601, in which control immediately passes to step 610.

In step 610, an external scan enable signal indicating transitions from scan mode to capture mode, and vice versa, may be received, for example, from test equipment 110. Thus, with reference to FIG. 2, a transition from logic high to logic low indicates transition to capture mode.

In step 620, a clock signal is received. The clock signal may correspond to signal 101 noted above with reference to FIG. 1, and thus may contain pulses which correspond to both low speed clock signal and high speed clock signal.

In step 650, an accurate scan enable is generated from the external scan enable signal with the transitions to capture mode being timed to be synchronous with the clock signal, and with the transitions to scan mode being asynchronous. The method ends in step 699.

As described below in further detail such an accurate scan enable signal overcomes one or more of the problems described above. The manner in which the scan enable signal may be generated is described below with some examples.

7. Presettable Circuit

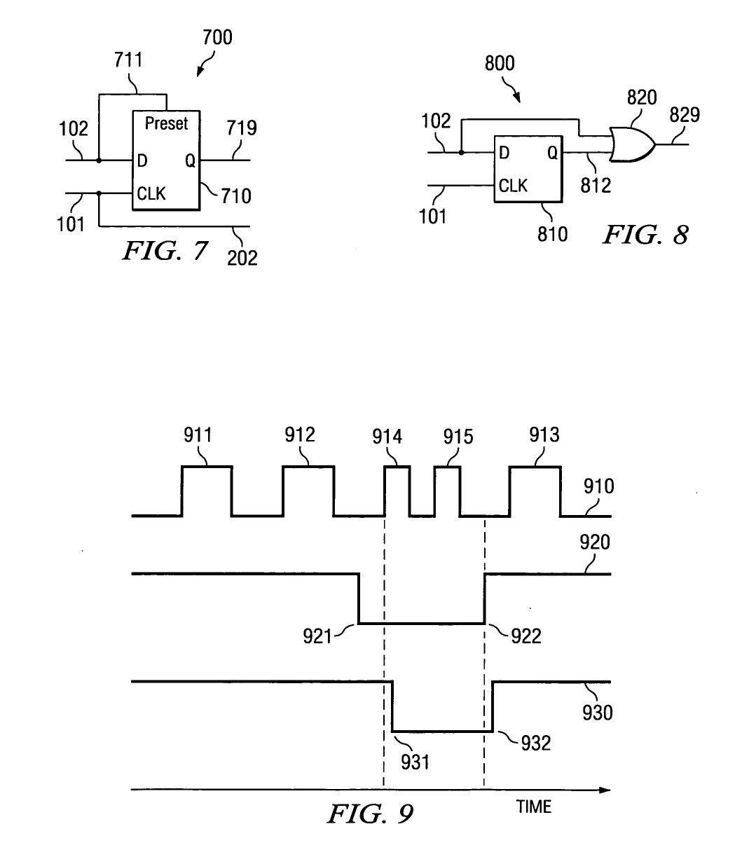

FIG. 7 is a block diagram illustrating the details of a presettable circuit, which generates an accurate scan enable signal in an embodiment of the present invention. Presettable circuit 700 is shown containing flip-flop 710 having D, clk and preset as input signals, and Q as output signal.

The clk and D inputs of flip-flop 710 are respectively connected to a clock signal on path 101 and external scan enable signal on path 102. The preset input is also connected to the external scan enable signal on path 102. The output Q of flip-flop 710 is provided as accurate scan enable signal se_int on path 719. Se_int 719 is further provided as scan enable on path 201 to scan register 200. Clock signal 101 is provided as clock 202 to scan register 200.

Flip-flop 710 forwards SE 102 received on D-input to output Q as se_int 719 at the rising edge of clock signal 101. For example, a logic high to logic low (deactivation) transition of SE 102 is provided as se_int 719 only at the time of rising edge of clock signal 101 (i.e., synchronously). However, a logic low to logic high transition of SE 102 is passed on as se_int 719 irrespective of the specific state of clock signal 101 as described below in further detail.

As is well known in relevant arts, preset input is a high priority input and thus a logic high on preset input will set output Q to logic high irrespective of the specific state of clock signal 101. Therefore, a logic low to logic high (activation) transition of SE 102 is provided as se_int 719 immediately (i.e., passed), irrespective of the state of clock signal 101 (i.e., asynchronously).

Thus, it may be noted that the activation of accurate scan enable signal se_int 719 is provided asynchronously and deactivation of se_int 719 is provided synchronously. The synchronous deactivation enables the integrated circuit to move to capture mode between the two high speed clock pulses, and the asynchronous activation enables the integrated circuit to move to scan mode at the rising edge of the first low speed clock pulse after the capture mode.

As a result, extra cycle delay may not be required from moving to scan mode from the capture mode. In addition, presettable circuit 700 is provided in the path of scan enable signal and no extra circuitry is provided in the path of clock signal in such an embodiment. Thus, clock balancing due to any extra circuitry may not be required. As a result, the clock path may be implemented without substantially complex logic. An alternative embodiment to generate the accurate scan enable signal is described below.

8. Alternative Embodiment

FIG. 8 is a block diagram illustrating the details of a gating circuit, which generates an accurate scan enable signal in an alternative embodiment of the present invention. Gating circuit 800 is shown containing flip-flop 810 and OR gate 820. Each component is described below in further detail.

Flip-flop 810 contains inputs D and clk, and output Q. The clk and D inputs of flip-flop 810 are respectively connected to a clock signal on path 101 and an external scan enable signal on path 102. Clock signal 101 is provided as clock 202 to scan register 200. The output Q of flip-flop 810 is provided on path 812.

OR gate 820 performs a logical OR operation of SE 102 and output Q 812, and provides the corresponding output on path 829 as accurate scan enable signal se_int. Signal se_int 829 is provided as scan enable on path 201 to scan register 200. Due to the logical OR operation, a logic low to logic high (activation) transition of SE 102 is provided as se_int 829 immediately (i.e., passed) irrespective of the value at output Q 812, and thus represents an asynchronous change. However, a logic high to logic low (deactivation) of SE 102 is provided as se_int 829 only at the time of rising edge of clock signal 101 as described below in further detail.

Flip-flop 810 forwards SE 102 received on D-input to output Q 812 at the rising edge of clock signal 101. For example, a logic high to logic low (deactivation) transition of SE 102 is provided on path 812 at the time of rising edge of clock signal 101. However, since output Q on path 812 is at logic high before the rising edge of clock signal 101, OR gate 820 provides logic high on path 829 even if OR gate 820 receives the deactivation (logic low) of SE 102 directly on one input.

After the rising edge of clock 101, OR gate 820 provides a logic low on path 829 since the deactivation of SE 102 is provided on path 812 only at the rising edge of clock 101, representing a synchronous change on path 829. Thus, it may be noted that the activation of accurate scan enable signal se_int 829 is provided asynchronously and deactivation of se_int 829 is provided synchronously.

The circuit of FIG. 8 provides similar advantages as those described above with reference to FIG. 7. The circuits of FIGS. 7 and 8 may be integrated within integrated circuit 150 consistent with the description and connections described above. It should be further understood that various alternative implementations may be provided without departing from the scope and spirit of various aspects of the present invention, as will be apparent to one skilled in the relevant arts. description is continued with reference to a timing diagram illustrating the operation of the various embodiments in further detail.

9. Timing Diagram

FIG. 9 is a timing diagram illustrating the relationship of various signals in generating an accurate scan enable signal according to various aspects of the present invention. Merely for illustration, the timing diagram is described with reference to FIG. 2.

Lines 910, 920 and 930 respectively represent clock signal 101, external scan enable SE 102 and the accurate scan enable signal (each of paths 719 and 829 of FIGS. 7 and 8 respectively). Line 910 is shown containing low speed clock pulses 911, 912 and 913, and high speed clock pulses 914 and 915.

Line 920 is shown at logic high (representing scan mode) at rising edge of clock pulses 911 and 912, and changes to logic low (capture mode) at time point 921 after the rising edge of clock pulse 912. The change after the rising edge of clock pulse 912 enables line 930 to change after the rising edge of clock pulse 914 since each of flip-flop 710 of FIG. 7 and flip-flop 810 of FIG. 8 propagates the change with respect to the clock signal on path 101.

In addition, line 920 is shown changing from logic low to logic high at time point 922 before the rising edge of clock pulse 913. The change at time point 922 enables line 930 also to change before the rising edge of clock pulse 913 since each of flip-flop 710 of FIG. 7 (due to the preset input) and OR gate 820 of FIG. 8 forwards the change immediately irrespective of the state of clock signal 101.

Line 930 is shown at logic high at the rising edge of clock pulses 911, 912 and 914 in scan mode, and changes to logic low at time point 931 after the rising edge of the clock pulse 914. The change after the rising edge of clock pulse 914 indicates the change between high speed clock pulses 914 and 915.

Line 930 changes synchronously at time point 931 since the change is after the rising edge of clock pulse 914 even if external scan enable signal 102 (line 920) changes much before, but after the rising edge of 912. In addition, the change after the rising edge of clock pulse 914 enables shifting of the last bit of a scan sequence. It may be observed that line 930 is at logic low during clock pulse 915, in which the outputs of combinational logic are captured.

In addition, line 930 is shown changing from logic low to high at time point 932 before the rising edge of clock pulse 913 and immediately after SE 102 (line 920) changes from logic low to high. The change at time point 932 indicates changing asynchronously since the change is irrespective of the edges of clock signal 101.

Thus, it may be noted that the asynchronous change at time point 932 does not require extra clock cycle to shift the data. In addition, in comparison to FIGS. 5A and 5B, the clock signal 101 need not be stopped for any duration and thus glitches may not be present in the clock signal due to the approaches of FIGS. 6 through 9. Merely for understandability, the manner in which the approaches described above can be used in the embodiments of FIGS. 1 and 2 is described below.

10. Testing Using Accurate Scan Enable Signal

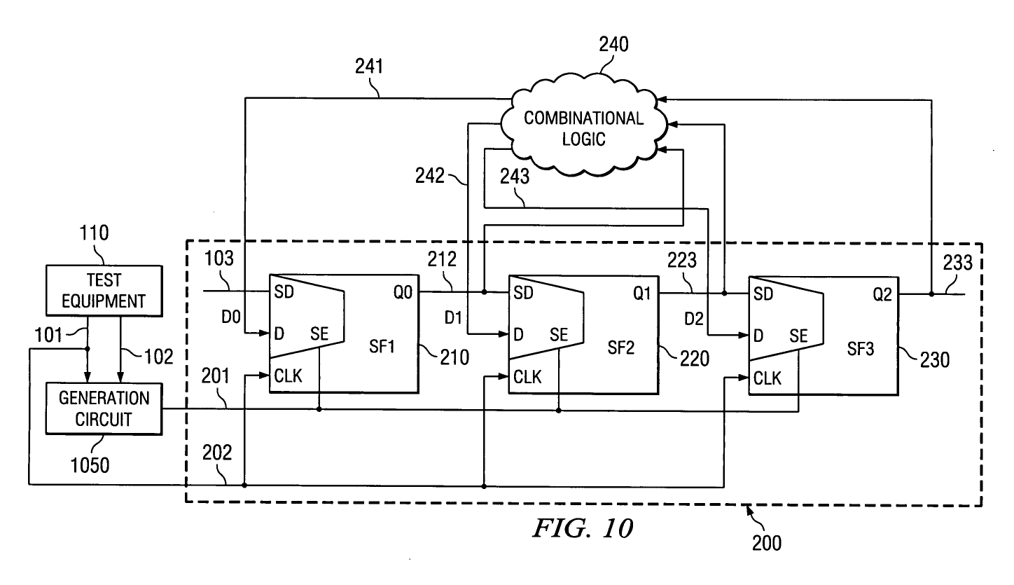

FIG. 10 is a block diagram illustrating the manner in which the embodiment(s) of FIG. 1 and FIG. 2 can be tested using an accurate scan enable signal generated according to various aspects of the present invention. Merely the differences from FIGS. 1 and 2 are described below for conciseness.

As may be readily observed, the diagram of FIG. 10 contains only generation circuit 1050 in addition to the components already depicted in FIGS. 1 and 2. Generation circuit 1050 may be implemented using the approaches described above with reference to FIGS. 6 through 9. Thus, generation circuit 1050 generates an accurate scan enable signal from external scan enable signal 102, and provides the generated signal on path 201. As a result, integrated circuit 150 may be tested accurately and quickly, as described above.

11. Conclusion

While various embodiments of the present invention have been described above, it should be understood that they have been presented by way of example only, and not limitation. Thus, the breadth and scope of the present invention should not be limited by any of the above described exemplary embodiments, but should be defined only in accordance with the following claims and their equivalents.

1. A method of generating an accurate scan enable signal when testing an integrated circuit using a sequential scanning technique, wherein said sequential scanning technique is designed to operate said integrated circuit in a scan mode if said accurate scan enable signal is at a first logic level and in a capture mode if said accurate scan enable signal is at a second logic level, said method comprising:
receiving a first scan enable signal having a first transition from said first logic level to said second logic level and a second transition from said second logic level to said first logic level; and
generating said accurate scan enable signal from said first scan enable signal by timing said first transition to be synchronous with a clock signal, and passing said second transition on said accurate scan enable signal asynchronously.

2. The method of claim 1, wherein said clock signal is used to clock a plurality of memory elements contained in said integrated circuit, said clock signal containing a plurality of low speed clock pulses in which a scan sequence is scanned into said plurality of memory elements in said scan mode, said clock signal further containing a plurality of high speed clock pulses in which said integrated circuit is operated in said capture mode.

3. The method of claim 2, wherein said first scan enable signal is received from a test equipment, wherein said first transition of said first scan enable signal is received before a rising edge of a first high speed clock pulse, and said second transition is received after said plurality of high speed clock pulses, wherein said first high speed clock pulse is contained in said plurality of high speed clock pulses.

4. A presettable circuit generating an accurate scan enable signal when testing an integrated circuit using a sequential scanning technique, wherein said sequential scanning technique is designed to operate said integrated circuit in a scan mode if said accurate scan enable signal is at a first logic level and in a capture mode if said accurate scan enable signal is at a second logic level, said presettable circuit comprises:
a flip-flop containing a preset input and an output, wherein said preset input is coupled to receive a first scan enable signal and said output is coupled to provide said accurate scan enable signal, whereby said accurate scan enable signal transitions to said first logic level asynchronously.

5. The presettable circuit of claim 4, said flip-flop further contains a data input and a clock input, wherein said data input and said clock input receive said first scan enable signal and a clock signal respectively, whereby said accurate scan enable signal transitions to said second logic level synchronously.

6. The presettable circuit of claim 5, wherein said clock signal is used to clock a plurality of memory elements contained in said integrated circuit, said clock signal containing a plurality of low speed clock pulses in which a scan sequence is scanned into said plurality of memory elements in said scan mode, said clock signal further containing a plurality of high speed clock pulses in which said integrated circuit is operated in said capture mode.

7. The presettable circuit of claim 7, wherein said first scan enable signal is received from a test equipment, wherein said first transition of said first scan enable signal is received before a rising edge of a first high speed clock pulse, and said second transition is received after said plurality of high speed clock pulses, wherein said first high speed clock pulse is contained in said plurality of high speed clock pulses.

8. The presettable circuit of claim 5, wherein said flip-flop comprises a D flip-flop.

9. A gating circuit generating an accurate scan enable signal when testing an integrated circuit using a sequential scanning technique, wherein said sequential scanning technique is designed to operate said integrated circuit in a scan mode if said accurate scan enable signal is at a first logic level and in a capture mode if said accurate scan enable signal is at a second logic level, said gating circuit comprises:
a flip-flop receiving a first scan enable signal as an input and being clocked by a clock signal, whereby transitions on an output of said flip-flop are synchronous with said clock signal; and
a logic gate receiving said first scan enable signal as a first input and said output of said flip-flop as another input, said logic gate generating said accurate scan enable signal as said output, said logic gate passing said first logic level received on said first scan enable signal to said output such that said accurate scan enable signal transitions asynchronously to said first logic level, and whereby transitions to said second logic level are synchronous with said clock signal.

10. The gating circuit of claim 9, wherein said logic gate comprises an OR gate.

11. The gating circuit of claim 10, wherein said flip-flop comprises a D-flop.

12. The gating circuit of claim 9, wherein said clock signal is used to clock a plurality of memory elements contained in said integrated circuit, said clock signal containing a plurality of low speed clock pulses in which a scan sequence is scanned into said plurality of memory elements in said scan mode, said clock signal further containing a plurality of high speed clock pulses in which said integrated circuit is operated in said capture mode.

13. The gating circuit of claim 11, wherein said first scan enable signal is received from a test equipment, wherein said first transition of said first scan enable signal is received before a rising edge of a first high speed clock pulse, and said second transition is received after said plurality of high speed clock pulses, wherein said first high speed clock pulse is contained in said plurality of high speed clock pulses.

14. An apparatus generating an accurate scan enable signal when testing an integrated circuit using a sequential scanning technique, wherein said sequential scanning technique is designed to operate said integrated circuit in a scan mode if said accurate scan enable signal is at a first logic level and in a capture mode if said accurate scan enable signal is at a second logic level, said apparatus comprising:
means for receiving a first scan enable signal having a first transition from said first logic level to said second logic level and a second transition from said second logic level to said first logic level; and
means for generating said accurate scan enable signal from said first scan enable signal by timing said first transition to be synchronous with a clock signal, and passing said second transition on said accurate scan enable signal asynchronously.

15. The apparatus of claim 14, wherein said clock signal is used to clock a plurality of memory elements contained in said integrated circuit, said clock signal containing a plurality of low speed clock pulses in which a scan sequence is scanned into said plurality of memory elements in said scan mode, said clock signal further containing a plurality of high speed clock pulses in which said integrated circuit is operated in said capture mode.

16. The apparatus of claim 15, wherein said first scan enable signal is received from a test equipment, wherein said first transition of said first scan enable signal is received before a rising edge of a first high speed clock pulse, and said second transition is received after said plurality of high speed clock pulses, wherein said first high speed clock pulse is contained in said plurality of high speed clock pulses.

17. An integrated circuit comprising:
a combinational logic generating a plurality of outputs based on a plurality of inputs;
a plurality of memory elements connected in sequence and being clocked by a clock signal, each of said plurality of memory elements operable in a scan mode or a capture mode according to an accurate scan enable signal, wherein a scan sequence is scanned into said plurality of memory elements as said plurality of inputs in said scan mode and said plurality of outputs are captured in said capture mode; and
a generation circuit receiving a first scan enable signal containing a first transition from said scan mode to said capture mode and a second transition from said capture mode to said scan mode, said generation circuit generating said accurate scan enable signal with said first transition being timed to be synchronous with said clock signal and with said second transition being asynchronous.

18. The integrated circuit of claim 17, wherein said clock signal contains a plurality of low speed clock pulses and a plurality of high speed clock pulses, wherein said integrated circuit is operated in said capture mode in a time duration corresponding to said high speed clock pulses and in said scan mode in a time duration corresponding to said low speed clock pulses.

19. The integrated circuit of claim 18, wherein said first scan enable signal is received from a test equipment, wherein said first transition of said first scan enable signal is received before a rising edge of a first high speed clock pulse, and said second transition is received after said plurality of high speed clock pulses, wherein said first high speed clock pulse is contained in said plurality of high speed clock pulses.
